(19) United States
(12) Patent Application Publication
(10) Pub. No.: US 2024/0213430 A1
(43) Pub. Date: Jun. 27, 2024

(54) SEMICONDUCTOR LIGHT EMITTING DEVICE AND METHOD OF MANUFACTURING THE SAME

(71) Applicant: SAMSUNG ELECTRONICS CO., LTD., Suwon-si (KR)

(72) Inventors: Dongwoo KIM, Suwon-si (KR); Joongil LEE, Suwon-si (KR); Jiheon OH, Suwon-si (KR); Kwonjoong KIM, Suwon-si (KR)

(73) Assignee: SAMSUNG ELECTRONICS CO., LTD., Suwon-si (KR)

(21) Appl. No.: 18/393,226

(22) Filed: Dec. 21, 2023

(30) Foreign Application Priority Data
Dec. 22, 2022 (KR) 10-2022-0182165

(51) Int. Cl. H01L 33/62; H01L 23/00; H01L 25/075

(52) U.S. Cl. CPC H01L 33/62; H01L 24/05; H01L 24/06; H01L 24/45; H01L 24/48; H01L 25/0753; H01L 2224/05571; H01L 2224/06152; H01L 2224/06155; H01L 2224/45124; H01L 2224/45144; H01L 2224/45147; H01L 2224/45169; H01L 2224/48095; H01L 2224/48157; H01L 2924/0132

(57) ABSTRACT

A semiconductor light emitting device includes: a substrate; a light emitting device provided on an upper surface of the substrate; a first pad provided on the upper surface of the substrate; a second pad provided on the upper surface of the light emitting device; a bonding wire connecting the light emitting device to the substrate, the bonding wire including: a first portion connected to and extending in a vertical direction from the first pad; a second portion extending from the first portion and inclined at a first angle relative to the first portion; a third portion extending from the second portion and inclined at a second angle is in a range of from about 125 degrees to about 150 degrees relative to the second portion; and a fourth portion extending from the third portion, inclined at a third angle relative to the third portion, and connected to the second pad; and a seal covering at least one side surface of the light emitting device and sealing the bonding wire on the substrate.

### CROSS-REFERENCE TO RELATED APPLICATION

This application is based on and claims priority under 35 U.S.C. § 119 to Korean Patent Application No. 10-2022-0182165, filed on Dec. 22, 2022, in the Korean Intellectual Property Office, the disclosure of which is incorporated by reference herein in its entirety.

### BACKGROUND

The present disclosure relates to a semiconductor light emitting device, and more particularly, to a pixel-type semiconductor light emitting device.

There has been an increasing demand for using semiconductor light emitting devices in various lighting apparatuses such as vehicle headlamps or indoor lighting. For example, in the case of using a light source module including a plurality of light emitting device chips, an intelligent lighting system has been proposed for implementing various lighting modes according to surrounding situations by separately controlling each light emitting device chip. However, in order to implement such an intelligent lighting system, the reliability of light emitting devices needs to be improved.

### SUMMARY

One or more example embodiments provide a pixel-type semiconductor light emitting device that may have excellent optical characteristics and reliability.

According to an aspect of an example embodiment, a semiconductor light emitting device includes: a substrate; a light emitting device provided on an upper surface of the substrate; a first pad provided on the upper surface of the substrate; a second pad provided on the upper surface of the light emitting device; a bonding wire connecting the light emitting device to the substrate, the bonding wire including: a first portion connected to and extending in a vertical direction from the first pad; a second portion extending from the first portion and inclined at a first angle relative to the first portion; a third portion extending from the second portion and inclined at a second angle is in a range of from about 125 degrees to about 150 degrees relative to the second portion; and a fourth portion extending from the third portion, inclined at a third angle relative to the third portion, and connected to the second pad; and a seal covering at least one side surface of the light emitting device and sealing the bonding wire on the substrate.

According to an aspect of an example embodiment, a semiconductor light emitting device includes: a substrate; a light emitting device mounted on an upper surface of the substrate; a first pad provided on the upper surface of the substrate; a second pad provided on the upper surface of the light emitting device; a bonding wire connecting the light emitting device to the substrate, the bonding wire including: a first portion connected to and extending in a vertical direction from a bump provided on the first pad; a second portion extending from the first portion and inclined at a first angle relative to the first portion; a third portion extending from the second portion and inclined at a second angle relative to the second portion; and a fourth portion extending from the third portion, inclined at a third angle relative to the third portion, and connected to the second pad; and a seal covering at least one side surface of the light emitting device and sealing the bonding wire on the substrate.

According to an aspect of an example embodiment, a semiconductor light emitting device includes: a substrate; a light emitting device mounted on an upper surface of the substrate; a first pad provided on the upper surface of the substrate; a second pad provided on the upper surface of the light emitting device; a bonding wire connecting the light emitting device to the substrate and including: a first portion extending in a vertical direction from the first pad; a second portion extending from the first portion and inclined at a first angle relative to the first portion; a third portion extending from the second portion and inclined at a second angle ranging from about 125 degrees to about 150 degrees relative to the second portion; and a fourth portion extending from the third portion, inclined at a third angle relative to the third portion, and connected to the second pad on the upper surface of the light emitting device; a seal covering at least one side surface of the light emitting device and sealing the bonding wire on the substrate; and a light emitting device driving circuit mounted on the upper surface of the substrate, wherein the light emitting device includes a base and a pixel light emitting structure provided on the base, and the pixel light emitting structure includes a plurality of light emitting stacks provided on the base in a matrix; a partition provided on the plurality of light emitting stacks and defining a plurality of pixel spaces respectively corresponding to the plurality of light emitting stacks; and a fluorescent layer provided in the plurality of pixel spaces.

### BRIEF DESCRIPTION OF THE DRAWINGS

The above and other aspects and features will be more apparent from the following description of one or more example embodiments taken in conjunction with the accompanying drawings, in which:

FIG. 1 is a cross-sectional view illustrating a semiconductor light emitting device according to one or more example embodiments;

FIG. 2 is an enlarged view of a portion of the semiconductor light emitting device of FIG. 1, according to one or more example embodiments;

FIG. 3 are images illustrating stress simulation results for a semiconductor light emitting device according to one or more example embodiments and a semiconductor light emitting device according to a comparative example at 125° C. and −45° C.;

FIGS. 4 and 5 are graphs illustrating thermal cycle test results for a semiconductor light emitting device according to a comparative example and a semiconductor light emitting device according to one or more example embodiments;

FIG. 6 is an external image of a semiconductor light emitting device according to a comparative example after a thermal cycle test;

FIG. 7 is a layout diagram of a light emitting device included in a semiconductor light emitting device according to one or more example embodiments;

FIG. 8 is a cross-sectional view taken along line A-A′ of FIG. 7 according to one or more example embodiments:

FIG. 9 is a cross-sectional view illustrating a semiconductor light emitting device according to one or more example embodiments;

FIG. 10 is a cross-sectional view illustrating a semiconductor light emitting device according to one or more example embodiments;

FIG. 11 is a cross-sectional view illustrating a semiconductor light emitting device according to one or more example embodiments;

FIG. 12 is a perspective view schematically illustrating a lighting apparatus including a semiconductor light emitting device according to one or more example embodiments;

FIGS. 13, 14, 15 and 16 are perspective views schematically illustrating lighting apparatuses including semiconductor light emitting devices according to one or more example embodiments;

FIG. 17 is a schematic diagram of an indoor lighting control network system including a semiconductor light emitting device according to one or more example embodiments; and

FIG. 18 is a schematic diagram of a network system including a semiconductor light emitting device according to one or more example embodiments.

### DETAILED DESCRIPTION

Hereinafter, example embodiments will be described in detail with reference to the accompanying drawings. Throughout the specification, like reference numerals will be used to denote like elements.

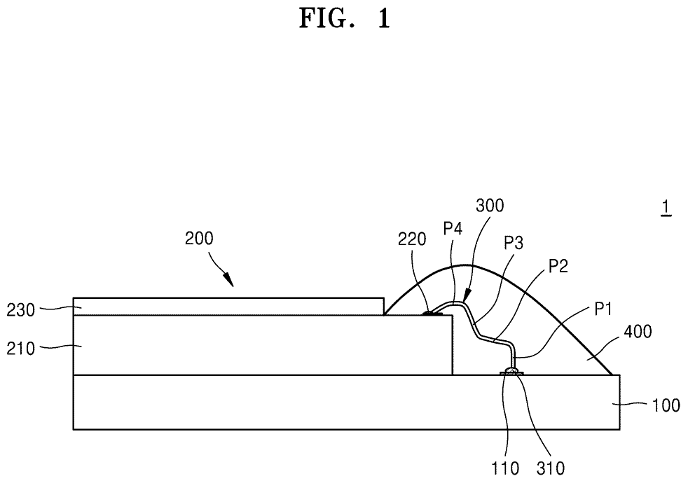

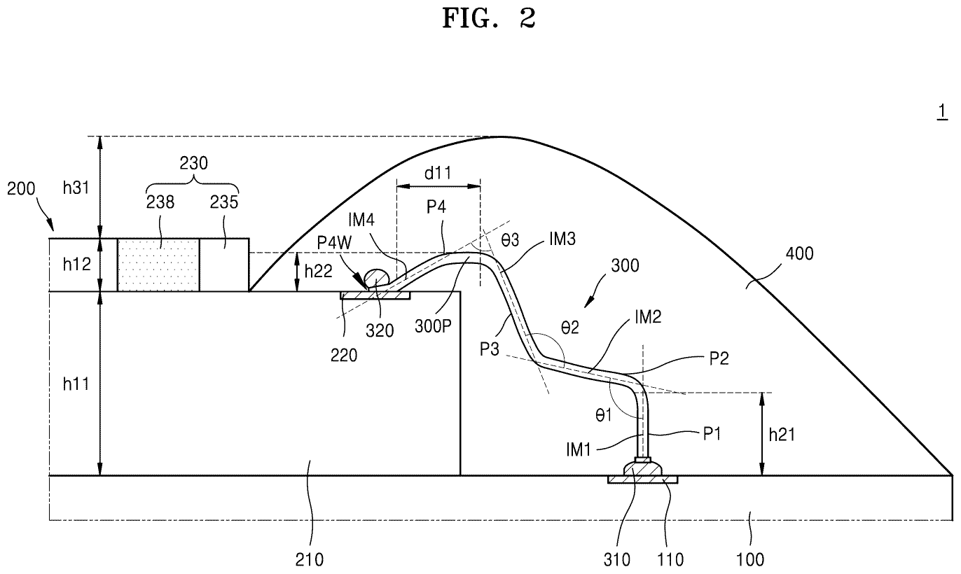

FIG. 1 is a cross-sectional view illustrating a semiconductor light emitting device according to one or more example embodiments. FIG. 2 is an enlarged view of a portion in FIG. 1 according to one or more example embodiments.

Referring to FIG. 1, a semiconductor light emitting device 1 may include a substrate 100, a light emitting device 200, a bonding wire 300, and a sealing material (or seal) 400.

The substrate 100 may include a package substrate or a printed circuit board. In one or more example embodiments, the substrate 100 may include a base plate including a metal material such as copper, and a wiring line pattern including one layer or two or more layers may be provided on the base plate. An insulating member may be provided on a portion of the upper surface of the substrate 100.

In one or more example embodiments, a first pad 110 may be provided on the upper surface of the substrate 100. The first pad 110 may be electrically connected to a light emitting device driving circuit provided outside the substrate 100 or a light emitting device driving circuit mounted on the substrate 100 through the wiring line pattern provided in the substrate 100. The first pad 110 may include copper (Cu), nickel (Ni), gold (Au), silver (Ag), or any combination thereof.

The light emitting device 200 may be mounted on the substrate 100. The light emitting device 200 may have a structure in which light is emitted from a plurality of light emitting structures provided in a pixel type. For example, the light emitting device 200 may be provided in a pixel type to be used in an intelligent lighting system such as a vehicle headlamp or indoor lighting, however, one or more example embodiments are not limited thereto.

In one or more example embodiments, the light emitting device 200 may include a base unit (or base) 210, a second pad 220, and a pixel light emitting structure 230.

In one or more example embodiments, the base unit 210 may include a silicon interposer and a wiring line layer provided on the silicon interposer. At least a portion of the upper surface of the base unit 210 may be covered by an insulating layer. In one or more example embodiments, the base unit 210 may be mounted on the substrate 100 by using an adhesive layer including a eutectic material such as AuSn or NiSi.

The second pad 220 may be provided on the upper surface of the base unit 210. The second pad 220 may be electrically connected to the wiring line layer included in the base unit 210. The second pad 220 may be provided in a peripheral area of the light emitting device 200 in plan view.

The pixel light emitting structure 230 may be provided on the upper surface of the base unit 210 and may be configured to emit light upward from the upper surface of the pixel light emitting structure 230, for example, to the outside of the semiconductor light emitting device 1. The pixel light emitting structure 230 may include a partition 235 and a fluorescent layer 238 surrounded by the partition 235, and the partition 235 and the fluorescent layer 238 may be provided at a higher level than the upper surface of the base unit 210.

In one or more example embodiments, the base unit 210 may have a first height h11 in a first direction perpendicular to the upper surface of the substrate 100, and the pixel light emitting structure 230 may have a second height h12 in the first direction. For example, the first height h11 may be about 300 micrometers to about 1.000 micrometers, and in one or more example embodiments, the first height h11 may be about 300 micrometers to about 600 micrometers. The second height h12 may be about 50 micrometers to about 200 micrometers, and in one or more example embodiments the second height h12 may be about 60 micrometers to about 120 micrometers. For example, the pixel light emitting structure 230 may be used for an intelligent lighting system such as a vehicle headlamp, and accordingly, the base unit 210 may include an electrical connection structure to the pixel light emitting structure 230 or may be formed to have a relatively great first height h11 in order to facilitate heat dissipation from the pixel light emitting structure 230.

The bonding wire 300 may be provided to electrically connect the first pad 110 provided on the substrate 100 with the second pad 220 provided on the light emitting device 200. A first end portion of the bonding wire 300 may be provided on a center portion of a first bump 310 provided on the upper surface of the first pad 110, and a second end portion of the bonding wire 300 may be provided on the upper surface of the second pad 220.

In one or more example embodiments, the bonding wire 300 may include gold (Au), aluminum (Al), platinum (Pt), copper (Cu), or any alloy thereof. Also, the first bump 310 may include the same material as the bonding wire 300. For example, the first bump 310 may include gold (Au), aluminum (Al), platinum (Pt), copper (Cu), or any alloy thereof.

In one or more example embodiments, the bonding wire 300 may be formed by a reverse wire bonding method. For example, the first bump 310 may be first provided on the first pad 110 provided on the substrate 100, and the bonding wire 300 connected thereto may be connected onto the second pad 220 on the light emitting device 200 to have an M-type shape and may be attached to the second pad 220 by a stitch process. For example, as illustrated in FIG. 2, the bonding wire 300 may include first, second, third and fourth portions P1, P2, P3, and P4 connected to each other at an inclination angle, and accordingly, the bonding wire 300 may have an M-type shape.

The first portion P1 may be provided to be connected to the center of the first bump 310 provided on the first pad 110 and may extend, for example, in the first direction (or the vertical direction). The first portion P1 may have a third height h21 in the first direction, and the third height h21 may correspond to about 30% to about 60% of the first height h11. In some examples, the third height h21 may be about 150 micrometers to about 250 micrometers.

The second portion P2 may be inclined and connected to the first portion P1 at a first angle θ1. The first angle θ1 between the second portion P2 and the first portion P1 may refer to, for example, an inclination angle between a first imaginary line IM1 in the extension direction of the first portion P1 and a second imaginary line IM2 in the extension direction of the second portion P2. For example, the first angle θ1 may be greater than 90 degrees and less than 135 degrees. Also, a connection portion between the first portion P1 and the second portion P2 may be provided as a curve having a relatively small curvature radius.

As illustrated in FIG. 2, the second portion P2 may be provided to be inclined such that the vertical position of the second portion P2 increases as the distance from the light emitting device 200 decreases. For example, a first point of the second portion P2 close to the light emitting device 200 may be provided at a higher level than a second point of the second portion P2 farther from the light emitting device 200. Also, as the second portion P2 may be connected to the first portion P1 at the first angle θ1 greater than 90 degrees and less than 135 degrees, the vertical position of the entire second portion P2 may be higher than the vertical position of the entire first portion P1 with respect to the upper surface of the substrate 100.

The third portion P3 may be inclined and connected to the second portion P2 at a second angle θ2. The second angle θ2 between the third portion P3 and the second portion P2 may refer to, for example, an inclination angle between the second imaginary line IM2 in the extension direction of the second portion P2 and a third imaginary line IM3 in the extension direction of the third portion P3. For example, the second angle θ2 may be about 125 degrees to about 150 degrees. Also, a connection portion between the second portion P2 and the third portion P3 may be provided as a curve having a relatively small curvature radius.

As illustrated in FIG. 2, the third portion P3 may be provided to be inclined such that the vertical position of the third portion P3 increases as the distance from the light emitting device 200 decreases. For example, a first point of the third portion P3 close to the light emitting device 200 may be provided at a higher level than a second point of the third portion P3 farther from the light emitting device 200. Also, as the third portion P3 is connected to the second portion P2 at the second angle θ2 of about 125 degrees to about 150 degrees, the vertical position of the entire third portion P3 may be higher than the vertical position of the entire second portion P2 with respect to the upper surface of the substrate 100. Also, a connection portion between the second portion P2 and the third portion P3 may be provided at a vertical level lower than the bottom surface of the fluorescent layer 238.

The fourth portion P4 may be inclined and connected to the third portion P3 at a third angle θ3. The third angle θ3 between the fourth portion P4 and the third portion P3 may refer to, for example, an inclination angle between the third imaginary line IM3 in the extension direction of the third portion P3 and a fourth imaginary line IM4 in the extension direction of the fourth portion P4. For example, the third angle θ3 may be about 60 degrees to about 120 degrees.

In one or more example embodiments, a connection portion between the third portion P3 and the fourth portion P4 may be provided as a curve having a relatively small curvature radius. The connection portion between the third portion P3 and the fourth portion P4 may be referred to as a peak portion 300P of the bonding wire 300, and the peak portion 300P may correspond to the highest point of the bonding wire 300 provided at the highest vertical level of the bonding wire 300.

As illustrated in FIG. 2, the fourth portion P4 may be provided to be inclined such that the vertical position of the fourth portion P4 decreases as the distance from the light emitting device 200 decreases. For example, a first point of the fourth portion P4 close to the light emitting device 200 (e.g., a first point of the fourth portion P4 closer to the second pad 220) may be provided at a lower level than a second point of the fourth portion P4 farther from the light emitting device 200 (e.g., a first point of the fourth portion P4 farther from the second pad 220).

An end portion of the fourth portion P4 may be provided on the second pad 220, and as illustrated in FIG. 2, a portion of the fourth portion P4 may form a wedge portion P4W extending at an inclination angle on the second pad 220. In the process of forming the bonding wire 300, the wedge portion P4W may be provided by a stitch process in which a portion of the fourth portion P4 of the bonding wire 300 is thermally compressed while being pulled in a direction toward the inside of the light emitting device 200.

A second bump 320 may be provided on the wedge portion P4W of the fourth portion P4. For example, the bottom surface of the second bump 320 may be provided to contact the upper surface of the wedge portion P4W. The second bump 320 may include the same material as the bonding wire 300. For example, the second bump 320 may include gold (Au), aluminum (Al), platinum (Pt), copper (Cu), or any alloy thereof.

The peak portion 300P of the bonding wire 300 may be located at a fourth height h22 from the upper surface of the light emitting device 200 (or the upper surface of the base unit 210 or the upper surface of the second pad 220), and in one or more example embodiments, the fourth height h22 may be about 60 micrometers to about 120 micrometers. For example, as the bonding wire 300 may have an M-shaped reverse bonding structure, the fourth height h22 of the peak portion 300P of the bonding wire 300 may be relatively small. Also, the peak portion 300P of the bonding wire 300 may be located at a first distance d11 from the second pad 220 in the horizontal direction, and the first distance d11 may be, for example, about 200 micrometers to about 400 micrometers.

The sealing material 400 may be provided on the substrate 100 to cover at least a portion of the upper surface and sidewall of the light emitting device 200 and may completely seal the bonding wire 300. For example, the sealing material 400 may have an upper surface located at a fifth height h31 from the upper surface of the light emitting device 200 (e.g., the upper surface of the pixel light emitting structure 230). In one or more example embodiments, the fifth height h31 may be about 300 micrometers to about 1,000 micrometers. In one or more example embodiments, a maximum height of the sealing material 400 in the first direction (or the vertical direction) may be in a range of from about 650 micrometers to about 2,200 micrometers. The sealing material 400 may include a transparent resin such as a silicon resin.

According to one or more example embodiments, the light emitting device 200 may include the base unit 210 and the pixel light emitting structure 230 and may be provided to have a relatively great height (e.g., a sum of the first height h11 and the second height h12). The bonding wire 300 may be curved to have an M-type shape by a reverse bonding method, and compared to a bonding wire according to a comparative example formed by a forward bonding method or a normal bonding method, the height of the peak portion 300P of the bonding wire 300 may be relatively small. Thus, the overall height of the sealing material 400 sealing the bonding wire 300 may also be reduced, and the sealing material 400 may be provided to have a relatively small volume.

In general, because a light emitting device used as a vehicle headlamp has a relatively great height, the height of a bonding wire provided around the light emitting device and the height of a sealing material tend to increase accordingly. As the height of the sealing material increases and the volume of the sealing material increases, a relatively great stress may be applied to the bonding wire due to repeated contraction and expansion of the sealing material according to the use of the light emitting device, and in this case, the reliability thereof may tend to degrade, such as the occurrence of a disconnection of the bonding wire or the occurrence of a detachment between the bonding wire and the pad.

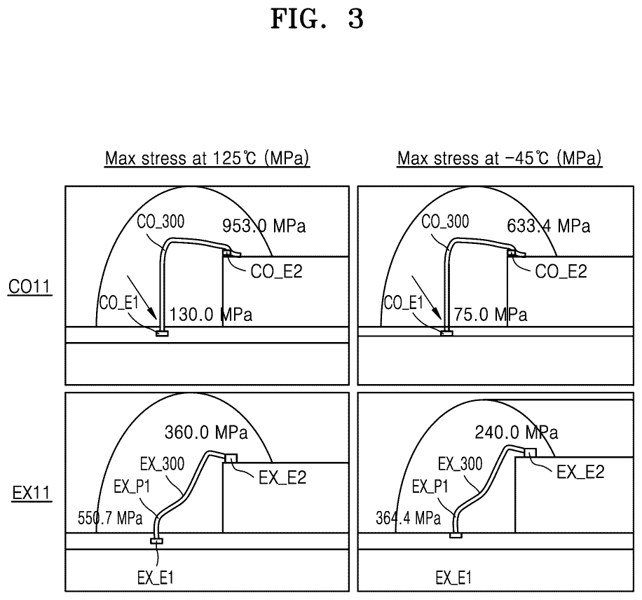

However, the semiconductor light emitting device 1 according to one or more example embodiments may include the M-shaped bonding wire 300 attached by a reverse bonding method, and the fourth portion P4 of the bonding wire 300 provided on the second pad 220 may include the wedge portion P4W. Accordingly, the height of the peak portion 300P of the bonding wire 300 may be relatively small, the overall height of the sealing material 400 sealing the bonding wire 300 may also be reduced, and the sealing material 400 may be provided to have a relatively small volume. Thus, even when the sealing material 400 is repeatedly contracted and expanded according to the use of the semiconductor light emitting device 1, the amount of a stress applied to the bonding wire 300 may be reduced and the reliability of the semiconductor light emitting device 1 may be improved. Stress evaluation and reliability test results according to bonding wires will be described below with reference to FIGS. 3, 4, 5 and 6.

FIG. 3 are images illustrating stress simulation results of a semiconductor light emitting device EX11 according to one or more example embodiments and a semiconductor light emitting device CO11 according to a comparative example at 125° C. and −45° C.

In FIG. 3, the semiconductor light emitting device EX11 according to one or more example embodiments has the structure described with reference to FIG. 2, and the semiconductor light emitting device CO11 according to a comparative example includes an inverted L-shaped bonding wire that is attached by a reverse bonding method and has one curved portion.

Referring to FIG. 3, in the semiconductor light emitting device CO11 according to a comparative example, at a temperature of 125° C., a stress of 130 MPa is applied to a region adjacent to a first end portion CO_E1 of a bonding wire CO_300, and a stress of 953 MPa is applied to a region adjacent to a second end portion CO_E2 of the bonding wire CO_300. At a temperature of −45° C., a stress of 75 MPa is applied to a region adjacent to the first end portion CO_E1 of the bonding wire CO_300, and a stress of 633.4 MPa is applied to a region adjacent to the second end portion CO_E2 of the bonding wire CO_300. That is, it may be seen that a relatively high stress is applied to the second end portion CO_E2 of the bonding wire CO_300 under severe conditions of high temperature and low temperature.

On the other hand, in the semiconductor light emitting device EX11 according to one or more example embodiments, at a temperature of 125° C., a stress of 550.7 MPa is applied to a curved portion of a first portion EX_P1 spaced apart by a certain distance from a first end portion EX_E1 of a bonding wire EX_300, and a stress of 360 MPa is applied to a region adjacent to a second end portion EX_E2 of the bonding wire EX_300. At a temperature of −45° C., a stress of 364.4 MPa is applied to a curved portion of the first portion EX_P1 spaced apart by a certain distance from the first end portion EX_E1 of the bonding wire EX_300, and a stress of 240 MPa is applied to a region adjacent to the second end portion EX_E2 of the bonding wire EX_300.

As illustrated in FIG. 3, it may be seen that the semiconductor light emitting device EX11 according to one or more example embodiments exhibits a more reduced maximum stress than the semiconductor light emitting device CO11 according to a comparative example at both the low and high temperatures. For example, the semiconductor light emitting device EX11 according to one or more example embodiments has a maximum stress reduction effect of about 42% compared to the semiconductor light emitting device CO11 according to a comparative example.

Also, in the semiconductor light emitting device EX11 according to one or more example embodiments, the position at which the maximum stress is applied may correspond not to an adhesion portion between the second end portion EX_E2 of the bonding wire EX_300 and the pad but to a middle portion of the bonding wire EX_300, for example, to a curved portion of the first portion EX_P1 of the bonding wire EX_300. Thus, as the amount of a stress applied between the second end portion EX_E2 of the bonding wire EX_300 and the pad is significantly reduced, it may be expected that the probability of occurrence of a defect such as a detachment or disconnection of the bonding wire at the second end portion EX_E2 will decrease.

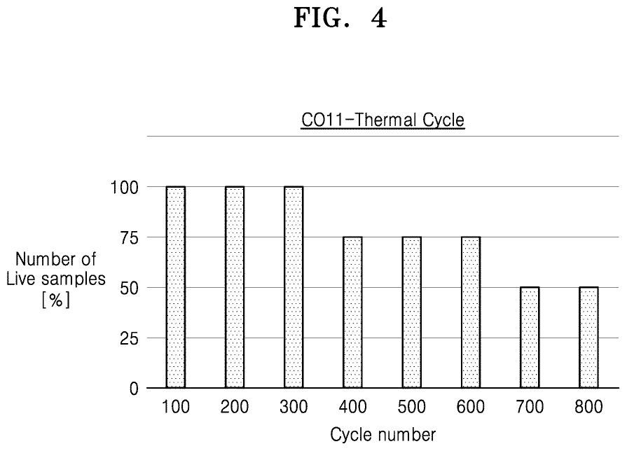

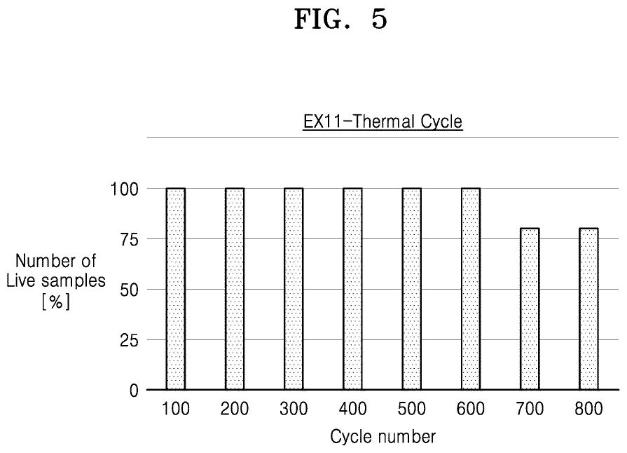

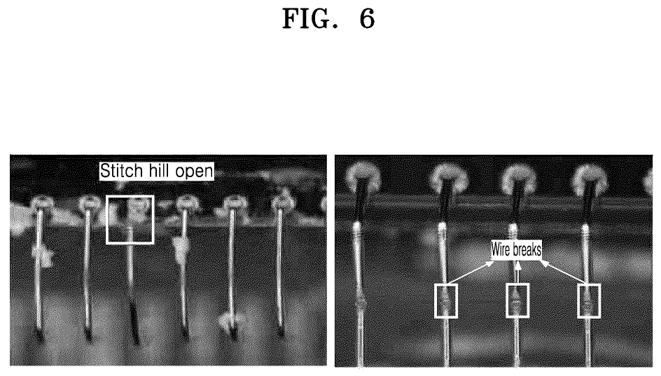

FIG. 4 shows a graph illustrating thermal cycle test results of the semiconductor light emitting device CO11 according to a comparative example. FIG. 5 shows a graph illustrating thermal cycle test results of the semiconductor light emitting device EX11, according to one or more example embodiments. FIG. 6 is an external image of the semiconductor light emitting device CO11 according to a comparative example after a thermal cycle test.

Referring to FIGS. 4, 5 and 6, a thermal cycle test or an accelerated life test was performed on the semiconductor light emitting device EX11 according to one or more example embodiments and the semiconductor light emitting device COIL according to a comparative example under the following conditions:

### [Thermal Cycle Test Conditions]

1 cycle: 30 minutes at −65° C.′ and then 30 minutes at 150° ° C. is defined as one cycle.
Tested up to 800 cycles in total.
Electrical characteristics were tested every 100 cycles and appearance defect factors were identified.

Referring to FIG. 4, in the semiconductor light emitting device CO11 according to a comparative example, defective samples occurred from the 400th cycle and defects occurred in 50% of samples in the 700th cycle and the 800th cycle.

Referring to FIG. 58, in the semiconductor light emitting device EX11 according to one or more example embodiments, a defective sample occurred first in the 700th cycle. In the 800th cycle, defects occurred only in 20% of samples and 80% of samples operated normally.

Referring to FIG. 6, in the semiconductor light emitting device CO11 according to a comparative example, which was determined to be defective in the thermal cycle test, it may be seen that the second end portion CO_E2 (see FIG. 3) of the bonding wire CO_300 is separated from the pad, lifted, and opened (in other words, open-circuited). Also, in the semiconductor light emitting device CO11 according to a comparative example, which was determined to be defective in the thermal cycle test, it may be seen that a disconnection occurred in a middle portion of the bonding wire CO_300. It may be inferred that this is highly related to a relatively high stress being applied to the second end portion CO_E2 of the bonding wire CO_300 in the stress simulation test described with reference to FIG. 3.

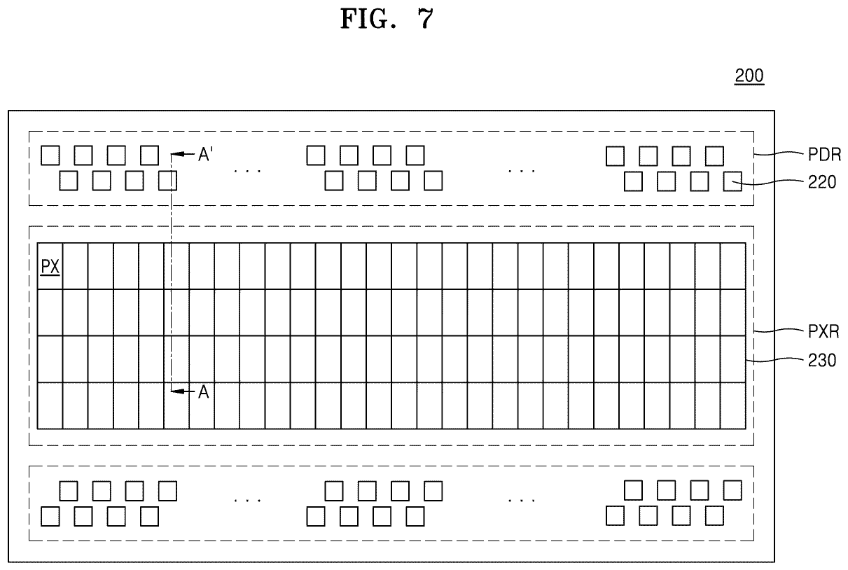

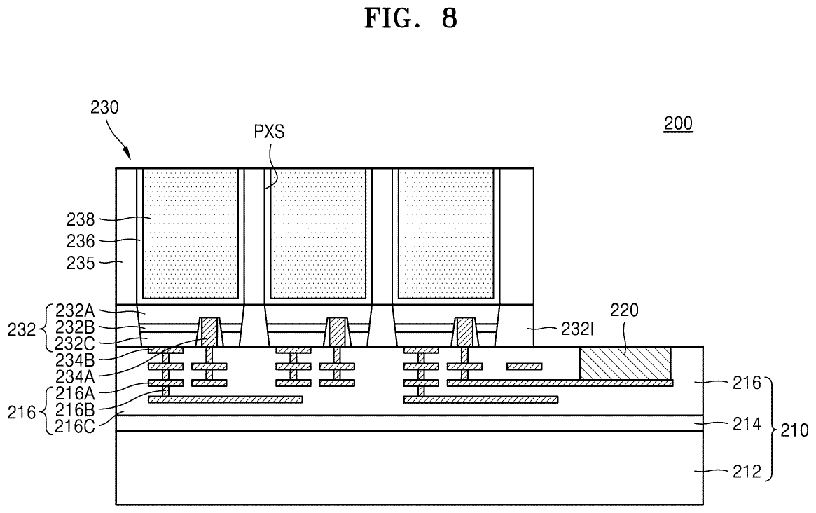

FIG. 7 is a layout diagram of a light emitting device 200 included in a semiconductor light emitting device 1 according to one or more example embodiments. FIG. 8 is a cross-sectional view taken along line A-A′ of FIG. 7 according to one or more example embodiments.

Referring to FIGS. 7 and 8, the light emitting device 200 may include a pixel area PXR and a pad area PDR surrounding the pixel area PXR. A pixel light emitting structure 230 provided in a matrix form may be provided on the pixel area PXR. A second pad 220 may be provided on the pad area PDR.

In one or more example embodiments, in plan view, the pixel area PXR may have an area corresponding to about 50% to about 90% of the total area of the light emitting device 200, and the pad area PDR may have an area corresponding to about 10% to about 50% of the total area of the light emitting device 200; however, one or more example embodiments is not limited thereto. In plan view, each pixel PX may have, for example, an X-direction width or a Y-direction width of about 10 μm to several millimeters (mm); however, one or more example embodiments is not limited thereto.

The pixel light emitting structure 230 may be provided on a base unit 210, and the base unit 210 may include a support substrate 212, an adhesive layer 214, and a wiring line structure 216. For example, the support substrate 212 may include a sapphire substrate, a glass substrate, a transparent conductive substrate, a silicon substrate, a silicon carbide substrate, or the like. The adhesive layer 214 may include an electrically insulating material, for example, resins or polymer materials such as silicon oxides, silicon nitrides, or UV-curable materials. In one or more example embodiments, the adhesive layer 214 may include a metallic adhesive material such as a eutectic material. The wiring line structure 216 may include a wiring line layer 216A, a via 216B, and an insulating layer 216C, and the wiring line layer 216A and the via 216B may be provided to supply power and/or signals from the second pad 220 to the pixel light emitting structure 230.

A plurality of light emitting stacks 232 may be provided in a matrix shape on the base unit 210 to correspond to each pixel PX. In plan view, a device isolation insulating layer 2321 may be provided between the plurality of light emitting stacks 232. A partition 235 may be provided on the plurality of light emitting stacks 232. The partition 235 may define a plurality of pixel spaces PXS to correspond to each pixel PX, and the upper surface of the plurality of light emitting stacks 232 may be exposed at a bottom portion of the plurality of pixel spaces PXS. A passivation layer 236 may be provided on the sidewall of the partition 235, and a fluorescent layer 238 may be provided on the partition 235 to fill the plurality of pixel spaces PXS.

The plurality of light emitting stacks 232 may include a first conductivity type semiconductor layer 232A, an active layer 232B, and a second conductivity type semiconductor layer 232C. A first electrode 234A electrically connected to the first conductivity type semiconductor layer 232A and a second electrode 234B electrically connected to the second conductivity type semiconductor layer 232C may be provided on the bottom surface of the plurality of light emitting stacks 232.

The first conductivity type semiconductor layer 232A may include a nitride semiconductor having a composition of n-type InₓAl_{y}Ga_{(1-x-y)}N (0≤x<1, 0≤y<1, 0≤x+y<1), and an n-type dopant may include, for example, silicon (Si). For example, the first conductivity type semiconductor layer 232A may include GaN including an n-type dopant.

In one or more example embodiments, the first conductivity type semiconductor layer 232A may include a first conductivity type semiconductor contact layer and a current diffusion layer. The dopant concentration of the first conductivity type semiconductor contact layer may be about 2×10¹⁸ cm⁻³ to about 9×10¹⁹ cm⁻³. The thickness of the first conductivity type semiconductor contact layer may be about 1 μm to about 5 μm. The current diffusion layer may include a structure in which a plurality of InₓAl_{y} Ga_{(1-x-y)}N (0≤x, y≤1, 0≤x+y≤1) layers having different compositions or having different dopant contents are alternately stacked. For example, the current diffusion layer may include an n-type superlattice structure in which n-type GaN layers and/or AlₓIn_{y} Ga_{z}N layers (0≤x, y, z≤1, x+y+z≠0)) each having a thickness of about 1 nm to about 500 nm are alternately stacked. The dopant concentration of the current diffusion layer may be about 2×10¹⁸ cm⁻³ to about 9×10₁₉ cm⁻³.

The active layer 232B may be provided between the first conductivity type semiconductor layer 232A and the second conductivity type semiconductor layer 232C and may emit light having a certain energy by recombination of electrons and holes. The active layer 232B may include a multiple quantum well (MQW) structure in which quantum well layers and quantum barrier layers are alternately stacked. For example, the quantum well layer and the quantum barrier layer may include Inₓ Al_{y} Ga_{(1-x-y)}N (0≤x, y≤1, 0≤x+y≤1) having different compositions. For example, the quantum well layer may include InₓGa₍₁₋ₓ₎N (0≤x≤1), and the quantum barrier layer may include GaN or AlGaN. The thicknesses of each of the quantum well layer and the quantum barrier layer may be about 1 nm to about 50 nm. The active layer 232B is not limited to the MQW structure and may include a single quantum well structure.

The second conductivity type semiconductor layer 232C may include a nitride semiconductor layer having a composition of p-type InₓAl_{y}Ga_{(1-x-y)}N (0≤x<1, 0≤y<1, 0≤x+y<1), and a p-type dopant may include, for example, magnesium (Mg).

In one or more example embodiments, the second conductivity type semiconductor layer 232C may include an electron blocking layer, a low-concentration p-type GaN layer, and a high-concentration p-type GaN layer provided as a contact layer. For example, the electron blocking layer may include a structure in which a plurality of InₓAl_{y} Ga_{(1-x-y)} N (0≤x, y≤1, 0≤x+y≤1) layers each having a thickness of about 5 nm to about 100 nm and having different compositions or different dopant contents are alternately stacked, or may include a single layer including Al_{y}Ga_{(1-y)}N (0<y≤1). The energy bandgap of the electron blocking layer may decrease away from the active layer 232B. For example, the Al composition of the electron blocking layer may decrease away from the active layer 232B.

The first conductivity type semiconductor layer 232A, the active layer 232B, and the second conductivity type semiconductor layer 232C may be sequentially stacked in the vertical direction and may be provided such that the upper surface of the first conductivity type semiconductor layer 232A may face the fluorescent layer 238 and the bottom surface of the second conductivity type semiconductor layer 232C may face the wiring line structure 216.

The first electrode 234A may be connected to the first conductivity type semiconductor layer 232A in an opening portion passing through the active layer 232B and the second conductivity type semiconductor layer 232C. The second electrode 234B may be provided on the bottom surface of the second conductivity type semiconductor layer 232C. The first electrode 234A and the second electrode 234B may include Ag, Al, Ni, Cr, Au, Pt. Pd. Sn. W, Rh, Ir, Ru, Mg, Zn, or any combination thereof. The first electrode 234A and the second electrode 234B may include a metal material having high reflectivity.

Alternatively, a reflection layer may be further provided on the sidewall of the partition 235, and the reflection layer may reflect light emitted from the light emitting stack 232. In one or more example embodiments, the reflection layer may include a metal layer including Ag, Al, Ni, Cr. Au. Pt, Pd, Sn, W, Rh, Ir, Ru, Mg, Zn, or any combination thereof. In one or more example embodiments, the reflection layer may include a resin layer such as polyphthalamide (PPA) containing a metal oxide such as a titanium oxide or an aluminum oxide. In one or more example embodiments, the reflection layer may include a distributed Bragg reflector layer. For example, the distributed Bragg reflector layer may include a structure in which a plurality of insulating layers having different refractive indexes are stacked repeatedly several to several hundred times. Each of the insulating layers included in the distributed Bragg reflector layer may include oxides or nitrides such as SiO₂, SiN, SiOₓN_{y}, TiO₂, Si₃N₄, Al₂O₃, TiN, AlN, ZrO₂, TiAlN, and TiSiN, or any combination thereof.

The fluorescent layer 238 may be provided to substantially fill the entire space of the plurality of pixel spaces PXS. The fluorescent layer 238 may include a single type of material capable of converting the light emitted from the light emitting stack 232 into a desired color, and thus, the fluorescent layer 238 related to the same color may be provided in the plurality of pixel spaces PXS. However, one or more example embodiments is not limited thereto. According to one or more example embodiments, the color of the fluorescent layer 238 provided in some pixel spaces PXS among the plurality of pixel spaces PXS may be different from the color of the fluorescent layer 238 provided in the other pixel spaces PXS.

The fluorescent layer 238 may include a resin having a fluorescent substance dispersed therein or a film including a fluorescent substance. For example, the fluorescent layer 238 may include a fluorescent film in which fluorescent particles are uniformly dispersed at a certain concentration. The fluorescent particles may include a wavelength conversion material for converting the wavelength of light emitted from a plurality of light emitting device structures. In order to improve the density of fluorescent particles and improve the color uniformity thereof, the fluorescent layer 238 may include two or more types of fluorescent particles having different size distributions.

In one or more example embodiments, the fluorescent substance may have various compositions and colors, such as oxides, silicates, nitrides, and fluorides. For example, the fluorescent substance may include β-SIAION: Eu²⁺ (green), (Ca,Sr)AlSiN₃:Eu²⁺ (red). La₃Si₆N₁₁:Ce³⁺ (yellow), Ka₂SiF₆:Mn₄_{⁺} (red), SrLiAl₃N₄:Eu (red), Ln₄₋ₓ(Eu_{z}M_{1-z})ₓSi_{12-y}Al_{y}O_{3+x+y}N_{18-x-y} (0.5≤x≤3, 0<z<0.3, 0<y≤4) (red), K₂TiF₆:Mn₄_{⁺} (red), NaYF₄:Mn₄_{⁺} (red), NaGdF₄:Mn₄_{⁺} (red), and/or the like. However, the type of the fluorescent substance is not limited thereto.

In one or more example embodiments, a wavelength conversion material such as quantum dots may be further provided over the fluorescent layer 238. The quantum dots may have a core-shell structure by using a III-V or II-VI compound semiconductor and may have a core such as CdSe or InP and a shell such as ZnS or ZnSe. Also, the quantum dots may include a ligand for stabilizing the core and the shell.

For an intelligent lighting system such as a vehicle headlamp, according to one or more example embodiments, the light emitting device 200 described with reference to FIGS. 7 and 8 may implement various lighting modes according to surrounding situations by separately controlling the light emitting stack 232 of each pixel PX. The partition 235 may prevent the light emitted from one pixel PX from mixing or penetrating into an adjacent pixel PX, and accordingly, the light emitting device 200 may have excellent contrast characteristics. Also, because the fluorescent layer 238 may be stably fixed in each pixel space PXS by the partition 235, when the light emitting device 200 is used as a vehicle headlamp, for example, even when repeated vibration and impact are applied thereto, the reliability of the light emitting device 200 may be improved due to excellent structural stability between the fluorescent layer 238 and the partition 235.

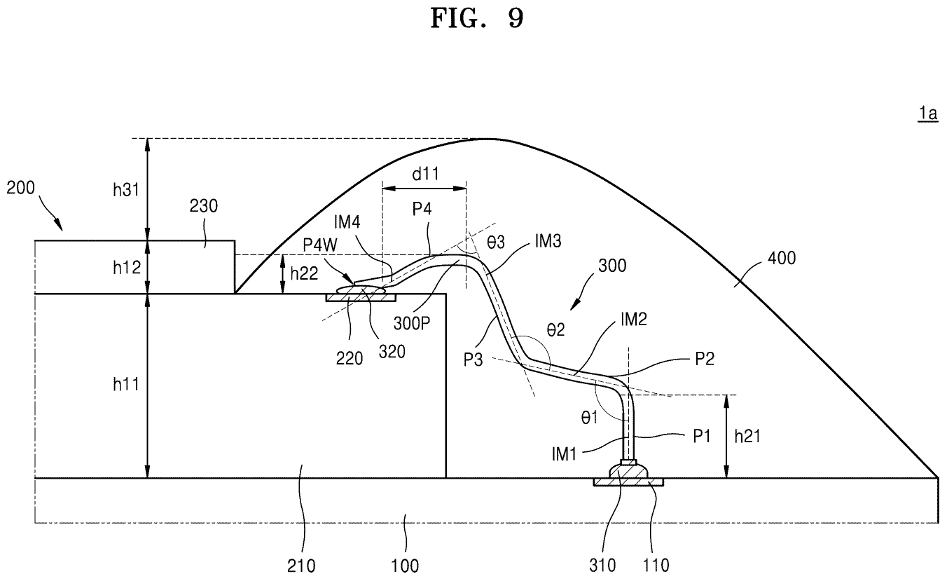

FIG. 9 is a cross-sectional view illustrating a semiconductor light emitting device 1a according to one or more example embodiments. In FIG. 9, like reference numerals as those in FIGS. 1, 2, 3, 4, 5, 6, 7 and 8 denote like elements.

Referring to FIG. 9, an end portion of the fourth portion P4 of the bonding wire 300 may be provided on the second pad 220, and as illustrated in FIG. 9, a portion of the fourth portion P4 may form a wedge portion P4W extending at an inclination angle on the second pad 220. The wedge portion P4W may be provided on the second bump 320. The bottom surface of the wedge portion P4W may contact the upper surface of the second bump 320, and the bottom surface of the second bump 320 may be provided on the second pad 220.

In the process of forming the bonding wire 300, the second bump 320 may be first provided on the second pad 220, and the wedge portion P4W may be provided on the second bump 320 by a stitch process in which a portion of the fourth portion P4 of the bonding wire 300 is thermally compressed while being pulled in a direction toward the inside of the light emitting device 200.

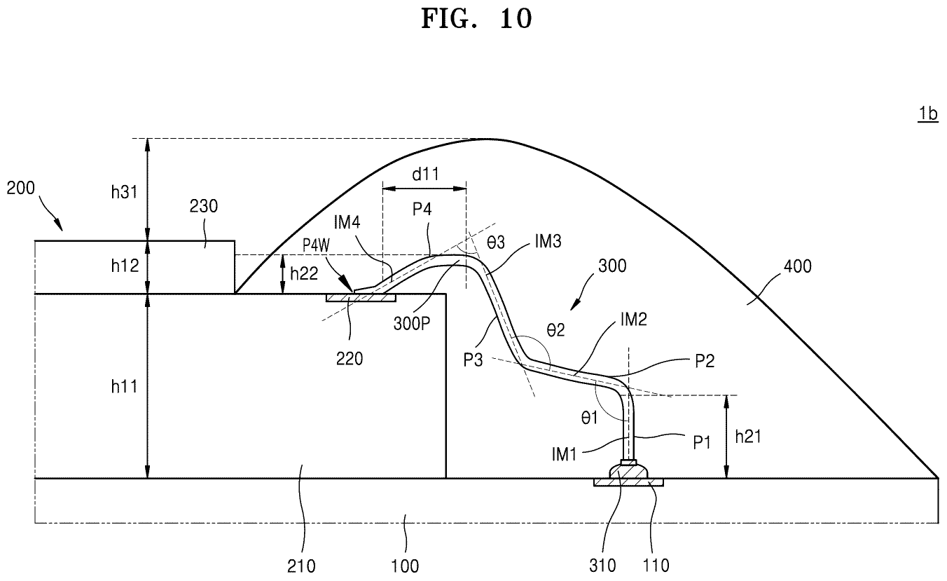

FIG. 10 is a cross-sectional view illustrating a semiconductor light emitting device 1b according to one or more example embodiments.

Referring to FIG. 10, an end portion of the fourth portion P4 of the bonding wire 300 may be provided on the second pad 220, and a portion of the fourth portion P4 may form a wedge portion P4W extending at an inclination angle on the second pad 220. According to one or more example embodiments, the second bump 320 described with reference to FIG. 2 may not be provided on the second pad 220.

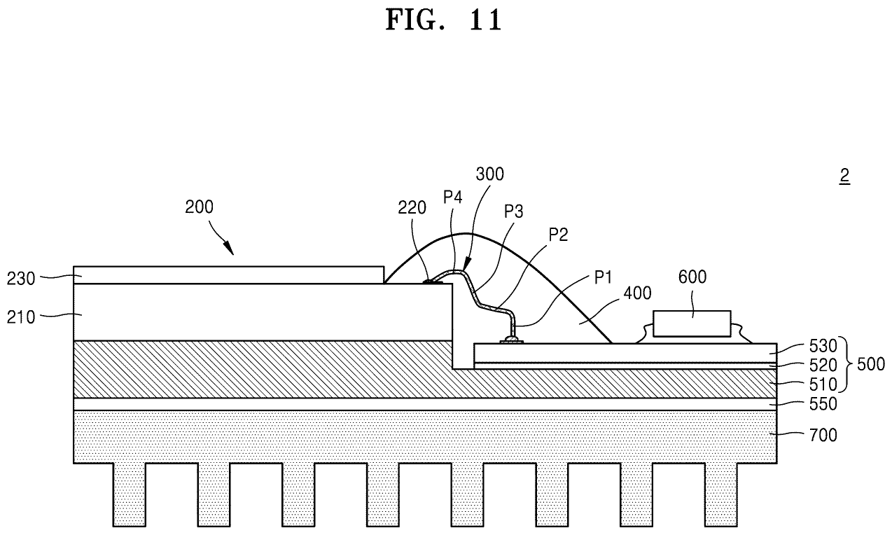

FIG. 11 is a cross-sectional view illustrating a semiconductor light emitting device 2 according to one or more example embodiments.

Referring to FIG. 11, a light emitting device 200 and a light emitting device driving circuit 600 may be mounted on a package substrate 500. The package substrate 500 may include a base plate 510 and an insulating layer 520 and an upper wiring line layer 530 provided on the base plate 510. The light emitting device driving circuit 600 may be mounted on the upper wiring line layer 530.

The light emitting device 200 may be mounted on the upper surface of the base plate 510 on a partial area of the package substrate 500. The base unit 210 of the light emitting device 200 may be attached to the upper surface of the base plate 510 by using a eutectic metal adhesive layer or the like.

The light emitting device driving circuit 600 may be electrically connected to the light emitting device 200 through the bonding wire 300. The light emitting device driving circuit 600 may be configured to separately or entirely drive a plurality of pixels PX (see FIG. 7) of the light emitting device 200.

A heat sink 700 may be attached to the bottom surface of the package substrate 500, and a thermal interface material (TIM) layer 550 may be further provided between the heat sink. 700 and the base plate 510.

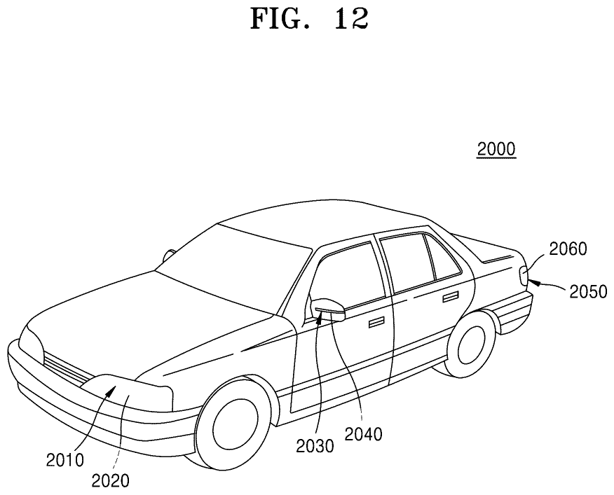

FIG. 12 is a perspective view schematically illustrating a lighting apparatus 2000 including a semiconductor light emitting device according to one or more example embodiments.

Referring to FIG. 12, a headlamp module 2020 may be installed in a head lamp unit 2010 of a vehicle, a side-view mirror lamp module 2040 may be installed in an external side-view mirror unit 2030, and a tail lamp module 2060 may be installed in a tail lamp unit 2050. At least one of the headlamp module 2020, the side-view mirror lamp module 2040, and the tail lamp module 2060 may include a light source module including at least one of the semiconductor light emitting devices 1, 1a, and 1b described above according to one or more example embodiments.

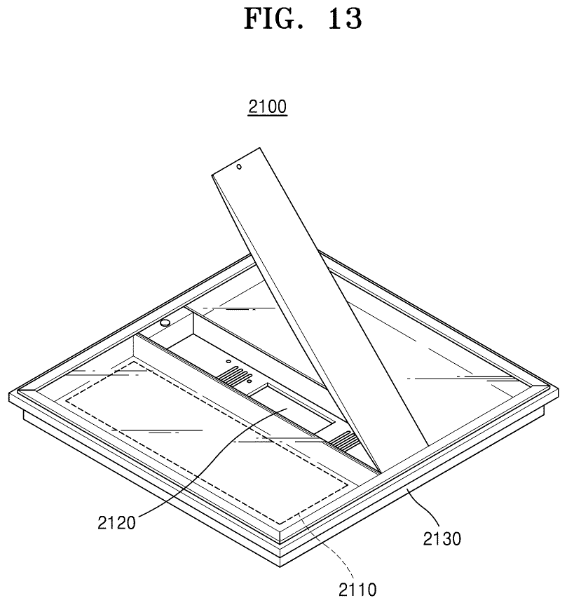

FIG. 13 is a perspective view schematically illustrating a flat panel lighting apparatus including a semiconductor light emitting device according to one or more example embodiments.

Referring to FIG. 13, a flat panel lighting apparatus 2100 may include a light source module 2110, a power supply device 2120, and a housing 2130.

The light source module 2110 may include a light emitting device array as a light source and may include at least one of the semiconductor light emitting devices 1, 1a, and 1b, described above according to one or more example embodiments, as a light source. The light source module 2110 may be provided to achieve a planar shape as a whole.

The power supply device 2120 may be configured to supply power to the light source module 2110. The housing 2130 may have an accommodation space for accommodating the light source module 2110 and the power supply device 2120 and may be provided in the shape of a hexahedron with one open side; however, one or more example embodiments is not limited thereto. The light source module 2110 may be provided to emit light to one open side of the housing 2130.

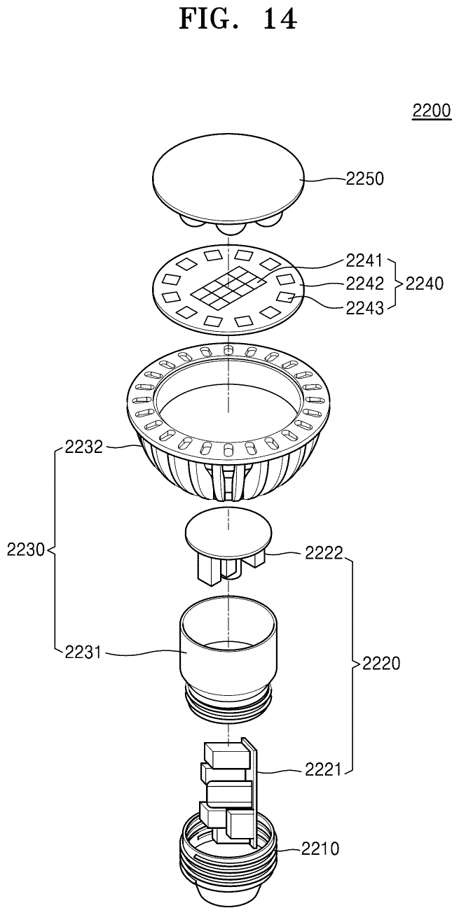

FIG. 14 is an exploded perspective view schematically illustrating a lighting apparatus including a semiconductor light emitting device according to one or more example embodiments.

Referring to FIG. 14, a lighting apparatus 2200 may include a socket 2210, a power supply unit 2220, a heat dissipation unit 2230, a light source module 2240, and an optical unit 2250.

The socket 2210 may be configured to be replaceable with a lighting apparatus. The power supplied to the lighting apparatus 2200 may be supplied through the socket 2210. The power supply unit 2220 may be divided into a first power supply unit 2221 and a second power supply unit 2222 that may be assembled thereinto. The heat dissipation unit 2230 may include an inner heat dissipation unit 2231 and an outer heat dissipation unit 2232, and the inner heat dissipation unit 2231 may be directly connected to the light source module 2240 and/or the power supply unit 2220 to transmit heat to the outer heat dissipation unit 2232. The optical unit 2250 may include an inner optical unit and an outer optical unit and may be configured to uniformly distribute the light emitted by the light source module 2240.

The light source module 2240 may receive power from the power supply unit 2220 to emit light to the optical unit 2250. The light source module 2240 may include one or more light emitting device packages 2241, a circuit board 2242, and a controller 2243, and the controller 2243 may store driving information of the light emitting device package 2241. The light emitting device package 2241 may include at least one of the semiconductor light emitting devices 1, 1a, and 1b, described above according to one or more example embodiments.

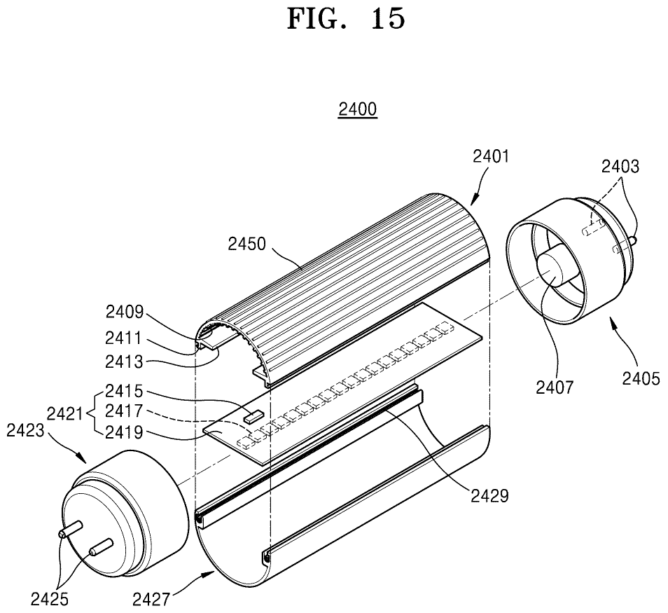

FIG. 15 is an exploded perspective view schematically illustrating a bar-type lighting apparatus including a semiconductor light emitting device according to one or more example embodiments.

Referring to FIG. 15, a lighting apparatus 2400 may include a heat dissipation member 2401, a cover 2427, a light source module 2421, a first socket 2405, and a second socket 2423. A plurality of heat dissipation fins 2450 and 2409 may be provided in an uneven shape on the inner and/or outer surface of the heat dissipation member 2401, and the heat dissipation fins 2450 and 2409 may be designed to have various shapes and spaces. A protruding support 2413 may be provided on the inner side of the heat dissipation member 2401. The light source module 2421 may be fixed to the support 2413. A locking jaw 2411 may be provided at both ends of the heat dissipation member 2401.

A locking groove 2429 may be provided at the cover 2427, and the locking jaw 2411 of the heat dissipation member 2401 may be coupled to the locking groove 2429 in a hook coupling structure. The positions of the locking groove 2429 and the locking jaw 2411 may be interchanged with each other.

The light source module 2421 may include a printed circuit board 2419, a light source 2417, and a controller 2415. The controller 2415 may store driving information of the light source 2417. Circuit lines for operating the light source 2417 may be provided at the printed circuit board 2419. Also, components for operating the light source 2417 may be included. The light source 2417 may include at least one of the semiconductor light emitting devices 1, 1a, and 1b, described above according to one or more example embodiments.

As a pair of sockets, the first and second sockets 2405 and 2423 may have a structure that is coupled to both ends of a cylindrical cover unit including the heat dissipation member 2401 and the cover 2427. For example, the first socket 2405 may include an electrode terminal 2403 and a power supply device 2407, and a dummy terminal 2425 may be provided at the second socket 2423. Also, an optical sensor and/or a communication module may be embedded in any one of the first socket 2405 and the second socket 2423.

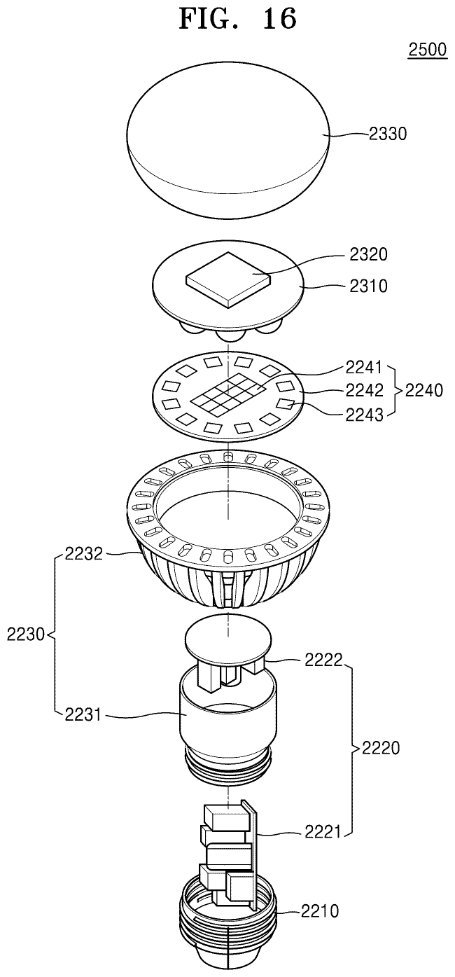

FIG. 16 is an exploded perspective view schematically illustrating a lighting apparatus including a semiconductor light emitting device according to one or more example embodiments.

Referring to FIG. 16, unlike the lighting apparatus 2200 described above, a lighting apparatus 2500 according to the present embodiment may include a reflection plate 2310 and a communication module 2320 on a light source module 2240. The reflection plate 2310 may uniformly distribute the light from the light source to the side and back to reduce dazzle.

The communication module 2320 may be mounted on the reflection plate 2310, and home-network communication may be implemented through the communication module 2320. For example, the communication module 2320 may include a wireless communication module based on ZigBee, Wi-Fi, or Li-Fi and may control lighting installed inside or outside the home, such as adjusting brightness or turning on/off the lighting apparatus through a smart phone or a wireless controller or may control electronic products and vehicle systems inside and outside the home, such as TVs, refrigerators, air conditioners, door locks, and vehicles. The reflection plate 2310 and the communication module 2320 may be covered by a cover unit 2330.

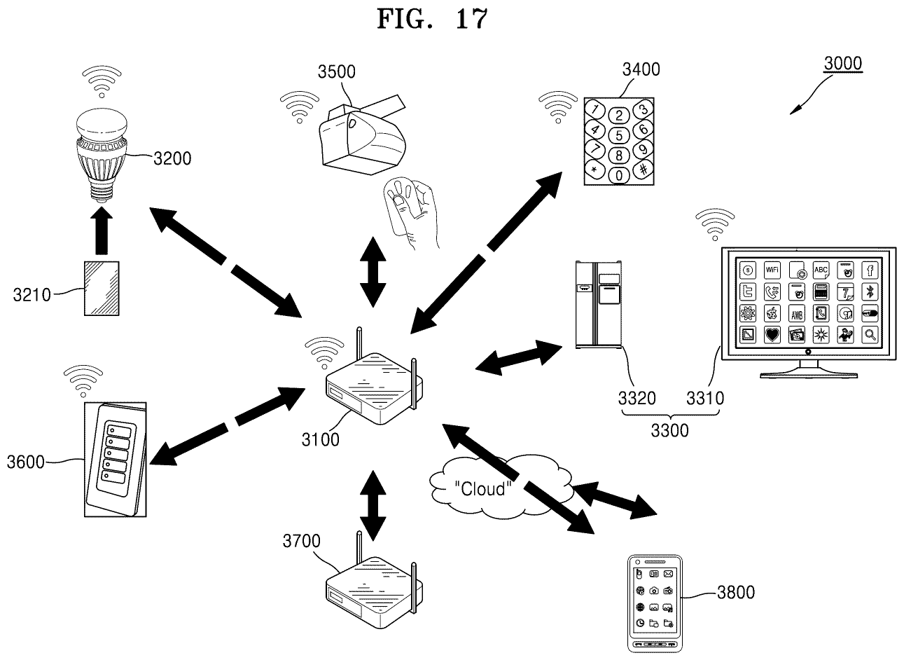

FIG. 17 is a schematic diagram for describing an indoor lighting control network system including a semiconductor light emitting device according to one or more example embodiments.

Referring to FIG. 17, a network system 3000 may include a complex smart lighting-network system in which a lighting technology based on light emitting devices such as LEDs, an Internet of things (IOT) technology, and a wireless communication technology are merged together. The network system 3000 may be implemented by using various lighting apparatuses and wired/wireless communication apparatuses or may be implemented based on an IoT environment to collect/process various information and provide the same to the user.

An LED lamp 3200 included in the network system 3000 may receive information about the surrounding environment from a gateway 3100 to control the lighting of the LED lamp 3200 and may check and control the operation state of other devices 3300 to 3800 included in the IoT environment based on a visible light communication function of the LED lamp 3200. The LED lamp 3200 may include at least one of the semiconductor light emitting devices 1, 1a, and 1b described above according to one or more example embodiments. The LED lamp 3200 may be communicatively connected to the gateway 3100 by a wireless communication protocol such as Wi-Fi. ZigBee, or Li-Fi and thus may include at least one lamp communication module 3210.

When the network system 3000 is applied to the home, a plurality of devices 3300 to 3800 may include home appliances 3300, a digital door lock 3400, a garage door lock 3500, a lighting switch 3600 installed on the wall, a router 3700 for wireless network relay, and a mobile device 3800 such as a smart phone, a tablet computer, or a laptop computer.

In the network system 3000, the LED lamp 3200 may check the operation states of various devices 3300 to 3800 by using a wireless communication network (e.g., ZigBee, Wi-Fi, or Li-Fi) installed in the home, or may automatically adjust the illuminance of the LED lamp 3200 according to the surrounding environments/situations. Also, Li-Fi communication based on the visible light emitted from the LED lamp 3200 may be used to control the devices 3300 to 3800 included in the network system 3000.

First, the LED lamp 3200 may automatically adjust the illuminance of the LED lamp 3200 based on the surrounding environment information received from the gateway 3100 through the lamp communication module 3210, or the surrounding environment information collected from the sensor mounted on the LED lamp 3200. For example, the lighting brightness of the LED lamp 3200 may be automatically adjusted according to the brightness of a screen or the type of a program broadcast on a television 3310. For this purpose, the LED lamp 3200 may receive the operation information of the television 3310 from the lamp communication module 3210 connected to the gateway 3100. The lamp communication module 3210 may be modularized as a united body with the controller and/or the sensor included in the LED lamp 3200.

For example, when a certain period of time has elapsed after the digital door lock 3400 is locked in the absence of a person in the home, all of the turned-on LED lamps 3200 may be turned off to prevent electricity waste. Alternatively, if a security mode is set through the mobile device 3800 or the like, when the digital door lock 3400 is locked in the absence of a person in the home, the LED lamp 3200 may be maintained in a turn-on state.

The operation of the LED lamp 3200 may be controlled according to the surrounding environment information collected through various sensors connected to the network system 3000. For example, when the network system 3000 is implemented in a building, the lighting, position sensors, and communication modules may be combined in the building to collect the position information of persons in the building to turn on or off the lighting, or to provide the collected information in real time to enable facility management or efficient use of idle space.

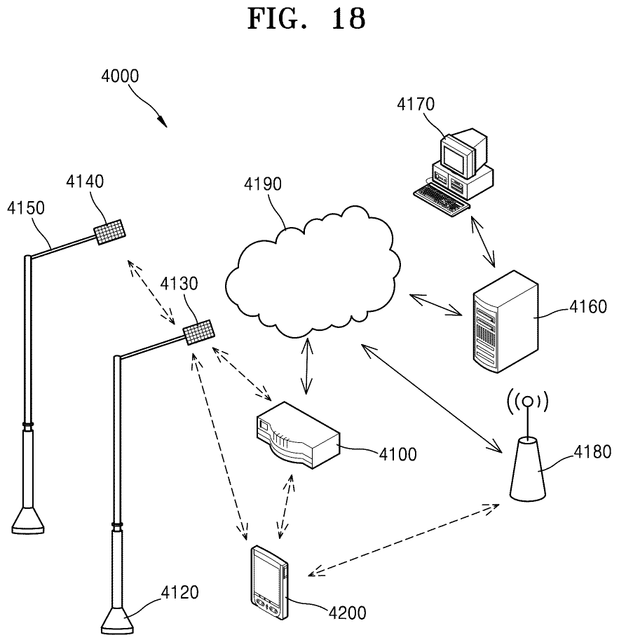

FIG. 18 is a schematic diagram for describing a network system including a semiconductor light emitting device according to one or more example embodiments.

Particularly, FIG. 18 illustrates one or more example embodiments of a network system 4000 applied to an open space. The network system 4000 may include a communication connection device 4100, a plurality of lighting apparatuses 4120 and 4150 that are installed at certain intervals and are communicatively connected to the communication connection device 4100, a server 4160, a computer 4170 for managing the server 4160, a communication base station 4180, a communication network 4190 for connecting communication equipment, and a mobile device 4200.

The plurality of lighting apparatuses 4120 and 4150 may be installed in an open outside space such as a street or a park and may include smart engines 4130 and 4140 respectively. The smart engines 4130 and 4140 may include a light emitting device for emitting light, a driving driver for driving the light emitting device, a sensor for collecting information about the surrounding environment, and a communication module. The light emitting device included in the smart engine may include at least one of the semiconductor light emitting devices 1, 1a, and 1b described above according to one or more example embodiments.

Through the communication module, the smart engines 4130 and 4140 may communicate with other peripheral equipment according to communication protocols such as Wi-Fi, ZigBee, and Li-Fi. One smart engine 4130 may be communicatively connected to another smart engine 4140, and Wi-Fi extension technology (Wi-Fi mesh) may be applied to communication between the smart engines 4130 and 4140. At least one smart engine 4130 may be connected by wired/wireless communication to the communication connection device 4100 connected to the communication network 4190.

As an access point (AP) capable of wired/wireless communication, the communication connection device 4100 may relay the communication between the communication network 4190 and other equipment. For example, the communication connection device 4100 may be connected to the communication network 4190 by at least one of wired/wireless methods and may be mechanically provided in any one of the lighting apparatuses 4120 and 4150.

The communication connection device 4100 may be connected to the mobile device 4200 through a communication protocol such as Wi-Fi. The user of the mobile device 4200 may receive surrounding environment information such as surrounding traffic information and weather information collected by the plurality of smart engines 4130 and 4140, through the communication connection device 4100 connected to the smart engine 4130 of the lighting apparatus 4120 adjacent thereto. The mobile device 4200 may be connected to the communication network 4190 through the communication base station 4180 by a wireless cellular communication method such as 3G or 4G.

Moreover, the server 4160 connected to the communication network 4190 may monitor the operation state of each lighting apparatus 4120 or 4150 while receiving the information collected by each smart engine 4130 or 4140 attached to each lighting apparatus 4120 or 4150. The server 4160 may be connected to the computer 4170 providing a management system, and the computer 4170) may execute software or the like capable of monitoring and managing the operation state of the smart engines 4130 and 4140.

While embodiments have been particularly shown and described above, it will be apparent to those skilled in the art that various changes in form and details may be made therein without departing from the spirit and scope of the following claims.

What is claimed is:

1. A semiconductor light emitting device comprising:
a substrate;
a light emitting device provided on an upper surface of the substrate;
a first pad provided on the upper surface of the substrate;
a second pad provided on the upper surface of the light emitting device;
a bonding wire connecting the light emitting device to the substrate, the bonding wire comprising:
a first portion connected to and extending in a vertical direction from the first pad;
a second portion extending from the first portion and inclined at a first angle relative to the first portion;
a third portion extending from the second portion and inclined at a second angle in a range of from about 125 degrees to about 150 degrees relative to the second portion; and
a fourth portion extending from the third portion, inclined at a third angle relative to the third portion, and connected to the second pad; and
a seal covering at least one side surface of the light emitting device and sealing the bonding wire on the substrate.

2. The semiconductor light emitting device of claim 1, wherein the second portion is inclined such that a vertical position of the second portion increases as the second portion extends toward the light emitting device, and
wherein the third portion is inclined such that a vertical position of the third portion increases as the third portion extends toward the light emitting device.

3. The semiconductor light emitting device of claim 2, wherein the fourth portion is inclined such that a vertical position of the fourth portion decreases as the fourth portion extends toward the light emitting device.

4. The semiconductor light emitting device of claim 2, wherein the first angle is greater than 90 degrees and less than 135 degrees.

5. The semiconductor light emitting device of claim 1, wherein the bonding wire has an “M” shape.

6. The semiconductor light emitting device of claim 1, wherein the light emitting device comprises a base having a first height in a first direction perpendicular to the upper surface of the substrate, wherein the first height is in a range of from about 300 micrometers to about 1,000 micrometers, and
wherein a maximum height of the seal in the first direction is in a range of from about 650 micrometers to about 2,200 micrometers.

7. The semiconductor light emitting device of claim 6, wherein the first portion has a second height in the first direction, and
wherein the second height is in a range of from about 30% to about 60% of the first height.

8. The semiconductor light emitting device of claim 1, wherein a bump is provided between the first portion of the bonding wire and the first pad, and
wherein the first portion is provided at a center of the bump.

9. The semiconductor light emitting device of claim 1, wherein the light emitting device comprises:
a base; and
a pixel light emitting structure provided on the base, and
wherein the second pad is provided on an upper surface of the base on a periphery of the light emitting device.

10. The semiconductor light emitting device of claim 9, wherein the pixel light emitting structure comprises:
a plurality of light emitting stacks provided on the base and provided in a matrix;
a partition provided on the plurality of light emitting stacks and defining a plurality of pixel spaces corresponding to the plurality of light emitting stacks; and
a fluorescent layer provided in the plurality of pixel spaces.

11. The semiconductor light emitting device of claim 10, wherein a connection portion between the second portion and the third portion is located at a vertical level lower than a vertical level of a bottom surface of the fluorescent layer.

12. A semiconductor light emitting device comprising:
a substrate;
a light emitting device mounted on an upper surface of the substrate;
a first pad provided on the upper surface of the substrate;
a second pad provided on the upper surface of the light emitting device;
a bonding wire connecting the light emitting device to the substrate, the bonding wire comprising:
a first portion connected to and extending in a vertical direction from a bump provided on the first pad;
a second portion extending from the first portion and inclined at a first angle relative to the first portion;
a third portion extending from the second portion and inclined at a second angle relative to the second portion; and
a fourth portion extending from the third portion, inclined at a third angle relative to the third portion, and connected to the second pad; and
a seal covering at least one side surface of the light emitting device and sealing the bonding wire on the substrate.

13. The semiconductor light emitting device of claim 12, wherein the second portion is inclined such that a vertical position of the second portion increases as the second portion extends toward the light emitting device, and
wherein the third portion is inclined such that a vertical position of the third portion increases as the third portion extends toward the light emitting device.

14. The semiconductor light emitting device of claim 13, wherein the fourth portion is inclined such that a vertical position of the fourth portion decreases as the fourth portion extends toward the light emitting device.

15. The semiconductor light emitting device of claim 13, wherein the first angle is greater than 90 degrees and less than 135 degrees, and
wherein the second angle is in a range of from about 125 degrees to about 150 degrees.

16. The semiconductor light emitting device of claim 12, wherein the light emitting device comprises a base having a first height in a first direction perpendicular to the upper surface of the substrate,
wherein the first height is in a range of from about 300 micrometers to about 1,000 micrometers,
wherein the first portion has a second height in the first direction, and
wherein the second height is in a range of from about 30% to about 60% of the first height.

17. The semiconductor light emitting device of claim 12, wherein the light emitting device comprises:
a base; and
a pixel light emitting structure provided on the base, and
wherein the second pad is provided on an upper surface of the base on a periphery of the light emitting device.

18. The semiconductor light emitting device of claim 17, wherein the pixel light emitting structure comprises:
a plurality of light emitting stacks provided on the base in a matrix;
a partition provided on the plurality of light emitting stacks and defining a plurality of pixel spaces respectively corresponding to the plurality of light emitting stacks; and
a fluorescent layer provided in the plurality of pixel spaces.

19. A semiconductor light emitting device comprising:
a substrate;
a light emitting device mounted on an upper surface of the substrate;
a first pad provided on the upper surface of the substrate;
a second pad provided on the upper surface of the light emitting device;
a bonding wire connecting the light emitting device to the substrate and comprising:
a first portion extending in a vertical direction from the first pad;
a second portion extending from the first portion and inclined at a first angle relative to the first portion;
a third portion extending from the second portion and inclined at a second angle ranging from about 125 degrees to about 150 degrees relative to the second portion; and
a fourth portion extending from the third portion, inclined at a third angle relative to the third portion, and connected to the second pad on the upper surface of the light emitting device;
a seal covering at least one side surface of the light emitting device and sealing the bonding wire on the substrate; and
a light emitting device driving circuit mounted on the upper surface of the substrate,
wherein the light emitting device comprises:
a base; and
a pixel light emitting structure provided on the base, and
wherein the pixel light emitting structure comprises:
a plurality of light emitting stacks provided on the base in a matrix;
a partition provided on the plurality of light emitting stacks and defining a plurality of pixel spaces respectively corresponding to the plurality of light emitting stacks; and
a fluorescent layer provided in the plurality of pixel spaces.

20. The semiconductor light emitting device of claim 19, wherein the base has a first height in a first direction perpendicular to the upper surface of the substrate,
wherein the first height is in a range of from about 300 micrometers to about 1,000 micrometers,
wherein a connection portion between the fourth portion and the third portion is provided at a first spacing distance from an end portion of the fourth portion provided on the second pad, and
wherein the first spacing distance is in a range of from about 200 micrometers to about 400 micrometers.
